(19) United States
(12) Patent Application Publication
(10) Pub. No.: US 2020/0275570 A1
(43) Pub. Date: Aug. 27, 2020

(54) ELECTRONICS CABINET FOR A VEHICLE AND ASSEMBLY METHOD FOR AN ELECTRONICS CABINET

(71) Applicant: SIEMENS MOBILITY GMBH, MUENCHEN (DE)

(72) Inventor: IOSSIF TOKMAN, NUERNBERG (DE)

(21) Appl. No.: 16/643,663

(22) PCT Filed: Jun. 25, 2018
(86) PCT No.: PCT/EP2018/066895

§ 371 Date: Mar. 2, 2020

(30) Foreign Application Priority Data
Aug. 31, 2017 (DE) 10 2017 215 235.4

(51) Int. Cl. H05K 5/04; H05K 5/02; H05K 7/14; H05K 7/18

(52) U.S. Cl. CPC H05K 5/04; H05K 5/0217; H05K 7/1427; H05K 7/18; H05K 7/1417

(57) ABSTRACT

An electronics cabinet, such as a cabinet for housing electronic components of a vehicle, such as a rail vehicle. The electronics cabinet has at least two cabinet walls and at least a portion of the cabinet walls are designed as supporting components. At least one supporting component is substantially made up of at least one or precisely one extruded profile. There is also described a method for assembling an electronics cabinet for installing electronics components of a vehicle, more particularly a rail vehicle. Initially, as part of a pre-assembly, at least one electronics component is assembled on an extruded profile for a cabinet case, a cabinet frame or a cabinet housing and/or a rear wall of the electronics cabinet. The at least two cabinet walls are only assembled together in their actual positions in the electronics cabinet temporally subsequently to this, as part of the final assembly.

The invention relates to an electronics cabinet, e.g. an electronics cabinet of a vehicle, in particular an electronics cabinet of a rail vehicle, for the installation of e-components of the vehicle, in particular of the rail vehicle. The invention also relates to a method for assembling an electronics cabinet, e.g. an electronics cabinet of a vehicle, in particular an electronics cabinet of a rail vehicle, for installation of e-components of the vehicle, in particular of the rail vehicle. In addition, the invention relates to a vehicle, in particular a rail vehicle.

In many technical areas, e.g. the construction of rail vehicles (engines, wagons), electrical and/or electronic components, for example involved in control technology and/or instrumentation and control technology, 19-inch e-components and possibly other mechanical, electrical and/or electronic arrangements, devices, components, units, systems, etc., have to be integrated in one or more supporting systems. These e-components are preferably installed in electronics cabinets (e here stands preferably for electrical and/or electronic) to provide for a better accessibility during startup and maintenance for example of the rail vehicle.

A housing of an electronics cabinet here serves to meet fire-protection requirements, ingress-protection requirements, and to provide for reliable fastening of the e-components (also: mechanical, etc., components), wiring and/or temperature control of the e-components, etc. In order for it to be possible for all the requirements to be met in reliable fashion, an electronics cabinet, e.g. for a rail vehicle, is of correspondingly robust configuration. The following problems arise again and again here: excessively high framework weights of the electronics cabinets, excessively high costs for producing and/or assembling the electronics cabinets, additional measures for fire protection and/or for cooling of the e-components, relatively high outlay for retrofitting/attachment of e-components, etc.

A housing of an electronics cabinet is generally manufactured from sheet steel and comprises a supporting framework, a protective cladding (walls: on the left, on the right, at the top, at the bottom, at the rear), at least one door wall and/or inspection flap and also at least one cable-entry point. A mechanically supporting structure comprises for example a supporting frame having a plurality of, often twelve, individual profiles plus corner connectors (eight). The manufacture of a large number of different individual parts gives rise to comparatively high material-related and production costs. The framework is usually riveted or welded. In the case of a welded framework, deformation of the cabinet surfaces (welding distortion) has to be expected; in the case of a riveted design, rivets are visible. In addition, elaborate measures are required for decorative surfaces (cladding parts, paint, etc.).

A basic problem with a sheet-steel structure is the weight of the mechanical parts. In the case of electronics cabinets, it is also the case that the e-components are installed in a finished housing, or the electronics cabinet, use being made at best of prefabricated installation panels. Cabinet wiring takes place at a point in time thereafter, which results in the high assembly costs. Cooling of the installed e-components takes place in dependence on dissipation of power from the installed e-units over a surface of the cabinet, are often also by virtue of ambient air being taken in. Additional fans and possibly filters are required for this purpose. This gives rise to additional costs for fire-protection measures, hardware, control systems, monitoring and assembly.

It is an object of the invention to specify an improved electronics cabinet, in particular for a vehicle, e.g. a rail vehicle. The electronics cabinet here is intended to be preferably more lightweight than comparable electronics cabinets in a comparable area of use and preferably more cost-effective. The intention is also for the electronics cabinet to be comparatively straightforward and quick, and therefore cost-effective, to assemble. Furthermore, it is an object of the invention to specify a corresponding vehicle, in particular a corresponding rail vehicle.

The object of the invention is achieved by means of an electronics cabinet, e.g. an electronics cabinet of a vehicle, in particular an electronics cabinet of a rail vehicle, for the installation of e-components of the vehicle, in particular of the rail vehicle; by a method for assembling an electronics cabinet, e.g. an electronics cabinet of a vehicle, in particular an electronics cabinet of a rail vehicle, for installation of e-components of the vehicle, in particular of the rail vehicle; and by means of a vehicle, in particular of a rail vehicle. Advantageous developments, additional features and/or advantages of the invention can be gathered from the dependent patent claims and/or from the following description of the invention.

The electronics cabinet according to the invention comprises at least two, three, four, five or six cabinet walls, wherein at least some of the cabinet walls are designed in the form of supporting parts, wherein at least one supporting part is essentially made up of at least one or precisely one preferred extruded profile. That is to say, the electronics cabinet can also be designed in the form of a partially open e-cage or the like. As its name suggests, a supporting part here performs an essential, mechanically supporting function for the relevant side of the electronics cabinet, its function not just being to be decorative and to provide insulation from the surroundings.

A respective supporting part can comprise a single preferred extruded profile or precisely two or more preferred extruded profiles. Instead of one or more extruded profiles, it is also possible for all the embodiments of the invention to make use of non-extruded profiles, wall profiles, wall parts, etc., e.g. made of a light metal, e.g. aluminum.

An e-component here is preferably an electrical and/or electronic component. In addition, or as an alternative, it is, of course, possible for an optical, a mechanical and/or a pneumatic component, etc., to be included here.

In one embodiment, one cabinet wall can be designed in the form of a door wall, and/or one cabinet wall can be designed in the form of a rear wall, of the electronics cabinet, wherein the cabinet wall and/or the rear wall is essentially made up of at least one or precisely one preferred extruded profile. In one embodiment, one, two, three, four or more cabinet walls can be designed in the form of a cabinet body, a cabinet frame or a cabinet housing, wherein the cabinet body, the cabinet frame or the cabinet housing is essentially made up of at least one or precisely one single preferred extruded profile.

In one embodiment, the/a cabinet body can have at least one (single and/or combined) supporting part, which (cabinet body) is made up of precisely one, precisely two or at least one preferred extruded profile. The/a cabinet frame can also have a maximum of three or precisely three (single and/or combined) supporting parts, which (cabinet frame) is made up of precisely one preferred extruded profile, precisely two preferred extruded profiles or at least one preferred extruded profile. In addition, the/a cabinet housing can have a maximum of four, precisely four or at least four (single and/or combined) supporting parts, which (cabinet housing) is made up of precisely one preferred extruded profile, precisely two preferred extruded profiles or at least one preferred extruded profile.

In one embodiment, the/a cabinet wall can comprise precisely one supporting part, which (cabinet wall) is made up of precisely one preferred extruded profile, precisely two preferred extruded profiles or at least one preferred extruded profile. The/a rear wall can also comprise precisely one supporting part, which (rear wall) is made up of precisely one preferred extruded profile, precisely two preferred extruded profiles or at least one preferred extruded profile. That is to say, instead of in each case one preferred extruded profile per wall, it is also possible to use a plurality of preferred extruded profiles, in particular two preferred extruded profiles (each referred to as a supporting part). Compatible extruded profiles here are connected to one another in a fixed manner, and preferably such that they can be released again, along their longitudinal sides.

In one embodiment, at least at a point in time prior to an assembly operation of the electronics cabinet, the cabinet body, the cabinet frame or the cabinet housing can be formed in one piece or integrally. Furthermore, the supporting part can be formed in one piece or integrally. In addition, at least at a point in time prior to an assembly operation of the electronics cabinet, supporting parts can be connected in one piece to one another or formed integrally. Furthermore, the cabinet wall can be formed in one piece or integrally. It is additionally possible, at least at a point in time prior to an assembly operation of the electronics cabinet, for cabinet walls to be connected in one piece to one another or formed integrally.

In one embodiment, all the cabinet walls or supporting parts of the electronics cabinet can be produced from precisely two, precisely three, precisely four, precisely five or precisely six different original extruded profiles. All the cabinet walls or supporting parts of the cabinet body, of the cabinet frame or of the cabinet housing can also be produced from precisely one original extruded profile or precisely two different, original extruded profiles. Furthermore, the door wall and/or the cabinet wall can each be produced from a single original extruded profile or from different original extruded profiles.

In one embodiment, the relevant extruded profile can be produced from a light metal, e.g. aluminum. The relevant extruded profile can also be designed essentially in the form of a solid profile. In addition, the relevant cabinet wall can be structured internally and/or externally. Furthermore, the relevant cabinet wall can have, on its inside, at least one longitudinal groove for the fastening of the relevant e-component. It is additionally possible for the electronics cabinet to have at least one e-component. The electronics cabinet according to the invention can be produced by an assembly method according to the invention.

In the case of the method according to the invention for assembling the electronics cabinet at least having two, three, four, five or six cabinet walls, within the context of a preassembly operation, at least one e-component is installed on a preferred extruded profile for a cabinet body, a cabinet frame or a cabinet housing and/or a rear wall of the electronics cabinet, wherein it is only at a point in time thereafter, within the context of a final assembly operation, that the at least two cabinet walls are installed on one another in their actual position in the electronics cabinet.

In preparation for the assembly method (i.e. at a point in time prior to the preassembly operation), a cutout and/or a bore can be made in an extruded profile for the cabinet body, the cabinet frame or the cabinet housing and/or the cabinet wall. A cutout and/or a beveled cutout can also be made, in a manner corresponding to a height and a width of the electronics cabinet, in the extruded profile for the cabinet body, the cabinet frame or the cabinet housing. Such a preferably V-shaped cutout and/or such a beveled cutout is preferably milled.

In preparation for the assembly method, it is also possible for the rear wall to be machined in a region around a longitudinal groove and/or in a region of a cooling device. In addition, the door wall can be machined in a region around a profile mount, a profile limb and/or a bent portion of a lug. The mechanical follow-up machining of the rear wall or of the extruded profile of the rear wall and/or of the door wall or of the extruded profile of the door wall takes place preferably by milling.

Within the context of the preassembly operation, the e-component can be installed in/on a longitudinal groove of the extruded profile for the cabinet body, the cabinet frame or the cabinet housing and/or the rear wall. The e-component can also be provided such that it can be displaced essentially continuously (in a stepless manner) along the longitudinal groove. Furthermore, a cable bushing and/or some other component can be installed on the extruded profile for the cabinet body, the cabinet frame or the cabinet housing and/or the rear wall.

Within the context of the final assembly operation, the extruded profile for the cabinet body, the cabinet frame or the cabinet housing in the first instance can be bent at an angle. That is to say, the extruded profile here preferably has an angle of approximately 90°. At a point in time thereafter, the rear wall can be installed at the angle of the extruded profile for the cabinet body, the cabinet frame or the cabinet housing. At a point in time thereafter, once again, the extruded profile for the cabinet body, the cabinet frame or the cabinet housing can be bent to form a U-shaped extruded profile on the rear wall. The extruded profile here preferably has two angles of approximately 90°.

At a point in time thereafter, the extruded profile for the cabinet body, the cabinet frame or the cabinet housing can be bent to form a circumferentially fully closed extruded profile on the rear wall. At a point in time thereafter, the door wall can be installed on the cabinet body, the cabinet frame or the cabinet housing. The electronics cabinet can be designed in the form of an electronics cabinet according to the invention. The vehicle according to the invention has an electronics cabinet according to the invention and/or an electronics cabinet produced according to the invention.

The vehicle according to the invention, in particular the rail vehicle according to the invention, has an electronics cabinet according to the invention. The invention can be applied, for example, to a rail vehicle (e.g.: railroad vehicle, traction vehicle, locomotive, power car, railcar, self-propelling special vehicle for rail-based tasks, railroad cars or wagons (rail vehicle without its own power unit), etc.) or a motor vehicle (e.g. passenger vehicle, bus, ATV (All Terrain Vehicle, off-road/military vehicle), commercial vehicle, heavy goods vehicle/truck, construction vehicle, special-purpose vehicle, construction machine, etc.), that is to say vehicles in general (including a wagon, that is to say a general vehicle without its own power unit). The invention can also be applied to a boat, a ship, an aircraft (means of transport) or a stationary electronics cabinet.

The invention gives rise to significant reductions in cost, significant reductions in weight and also a reduction in assembly-related outlay. In specific terms, the number of mechanical parts is vastly reduced in relation to the prior art. A reduction in weight of a mechanical fraction of the electronics cabinet amounts to up to 45%. A reduction in cost for material of the mechanical fraction of the electronics cabinet amounts to up to 40%. Using extruded profiles made of aluminum, and providing the possibility of forming a corrugated or ribbed surface, means that considerably more heat can be dissipated from the cabinet, which increases the service life of the e-components by virtue of the temperature level being comparatively low. It is also the case that the amount of energy required for active cabinet cooling decreases and makes a completely closed electronics cabinet possible.

According to the invention, the extruded profiles and structural parts are standardized. A large amount of the assembly work and wiring take place during a preassembly operation of the electronics cabinet (e.g. in an assembly or installation arrangement). This provides for better accessibility to the e-components and reduces assembly time and costs. Retrofitting of the electronics cabinet with e-components is possible with only a low level of outlay, because the grooves present in the multifunctional supporting parts and/or extruded profiles realize a flexible fastening system. It is also possible for electrical and/or electronic inserts to be straightforwardly displaced in the vehicle if required, even when they are in the installed state. The visible surfaces of the electronics cabinet have no rivet heads and/or areas of deformation. There is also a reduction in costs for painting and the design is improved.

The invention will be explained in more detail hereinbelow on the basis of exemplary embodiments and with reference to the accompanying schematic drawing, which is not true to scale. Parts, elements, structural parts, units, diagrams and/or components having an identical, univocal or analogous design and/or function are denoted by the same reference signs in the description of the figures (see below), the list of reference signs, the patent claims and in the figures (FIGs) of the drawing. A possible alternative which is not explained in the description of the invention (see above), is not illustrated in the drawing and/or is not limiting, a static and/or kinematic reversal, a combination, etc., with respect to the exemplary embodiments of the invention and/or a component, a diagram, a unit, a structural part, an element or a part thereof, can also be gathered from the list of reference signs and/or from the description of the figures.

In the case of the invention, a feature (part, element, structural part, unit, component, function, size, etc.) can be of positive configuration, i.e. present, or negative configuration, i.e. absent, wherein a negative feature is not explicitly explained as being a feature if it is not important according to the invention that it is absent. A feature from this specification (description, list of reference signs, patent claims, drawing) can be used not just in a manner specified, but also in some other manner (in isolation, in combination, as a replacement, addition, on its own, as an omission, etc.). In particular, it is possible to replace, add or omit a feature in the patent claims and/or the description on the basis of a reference sign and a feature assigned to the same, or vice versa, in the description, the list of reference signs, the patent claims and/or the drawing. Furthermore, this makes it possible to interpret and/or specify in more detail a feature in a patent claim.

The features from this specification (in view of the (mostly unknown) prior art) can also be interpreted as optional features; that is to say, each feature can be understood to be an optional, arbitrary or preferred, that is to say a non-mandatory, feature. Separation of a feature, possibly including its peripherals, from an exemplary embodiment is thus possible, and this feature can then be transferred to a generalized concept of the invention. The lack of a feature (negative feature) in an exemplary embodiment shows that the feature is optional as far as the invention is concerned. Also, a specific term for a feature can also be understood to be a generic term for the feature (possibly further hierarchical breakdown into sub-genre, sector, etc.), as a result of which, e.g. with account being taken of equivalent effect and/or equivalence, a generalization of a feature, or of this feature, is possible.

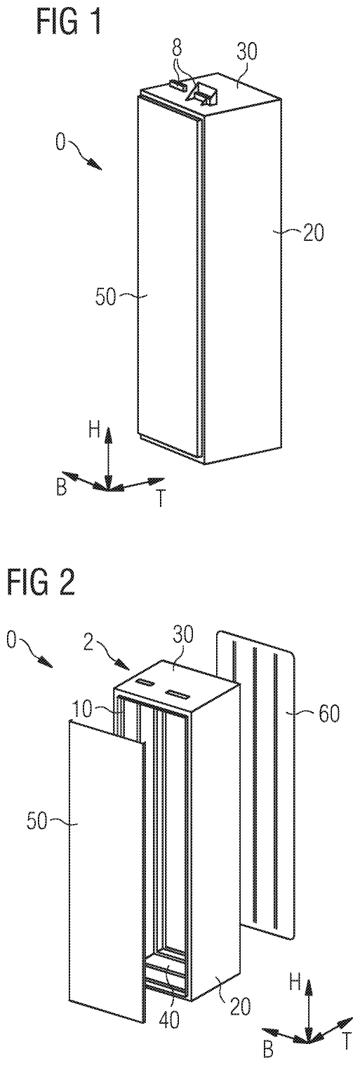

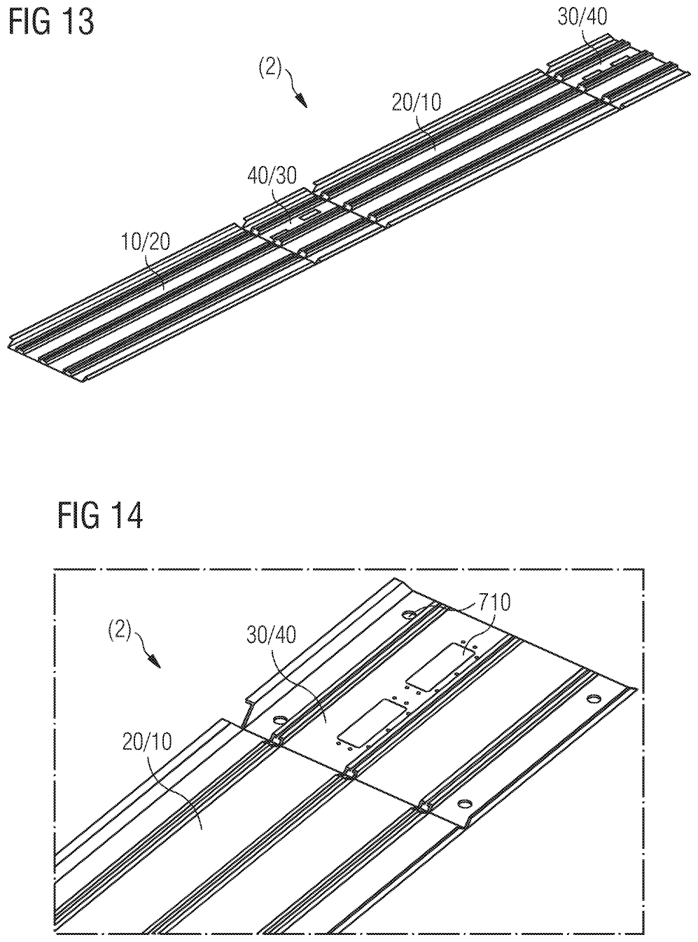

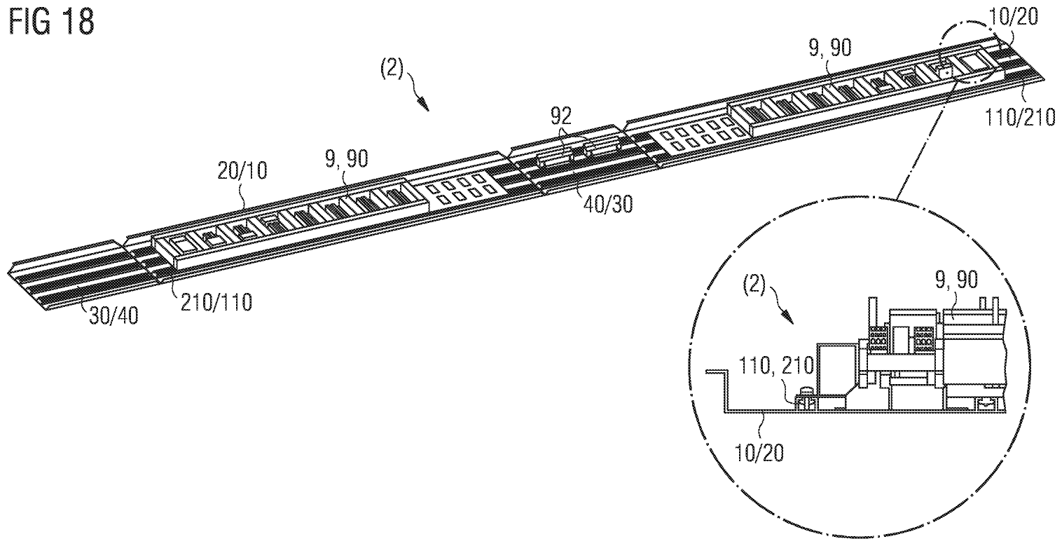

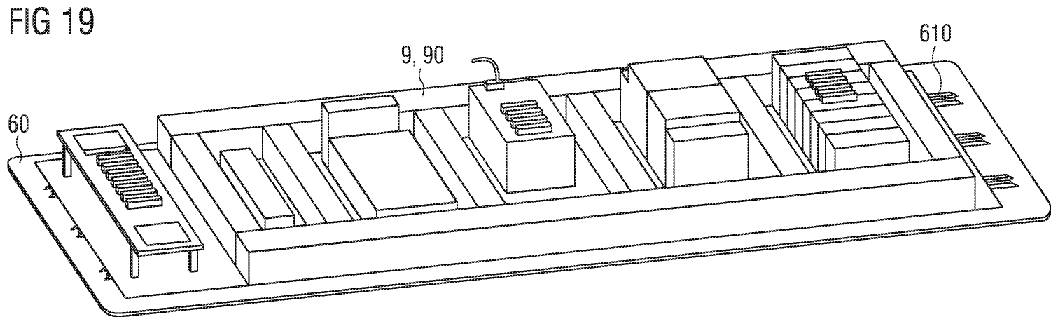

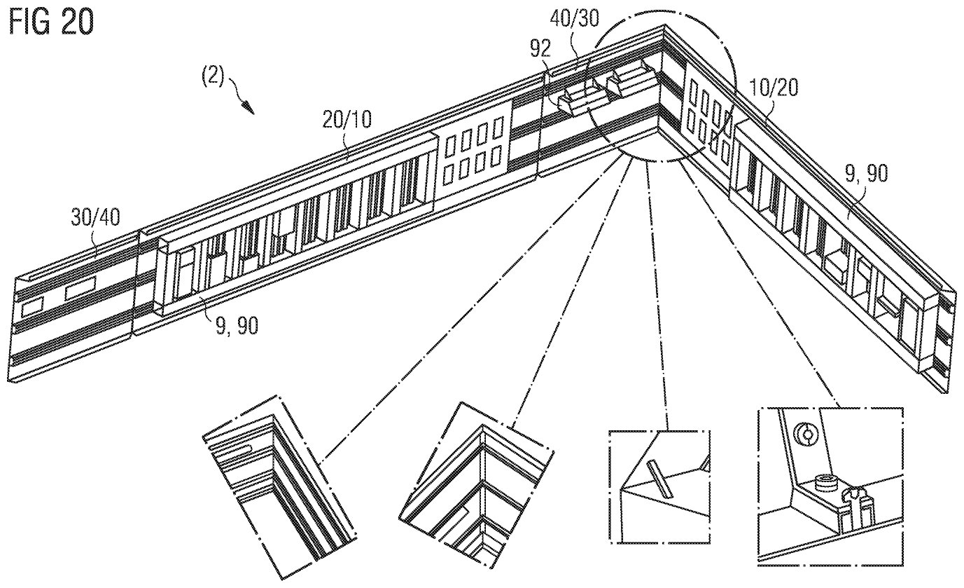

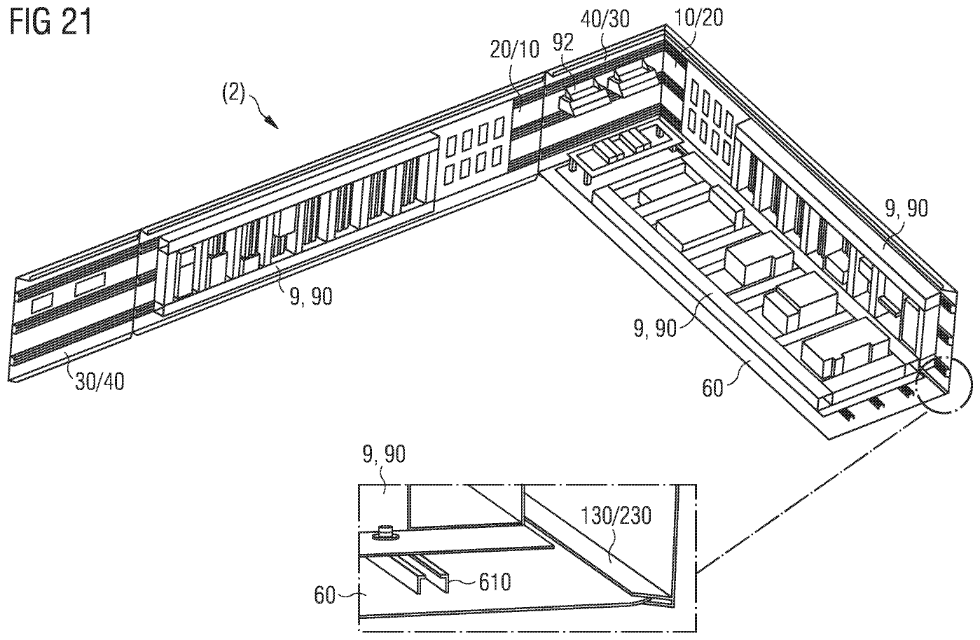

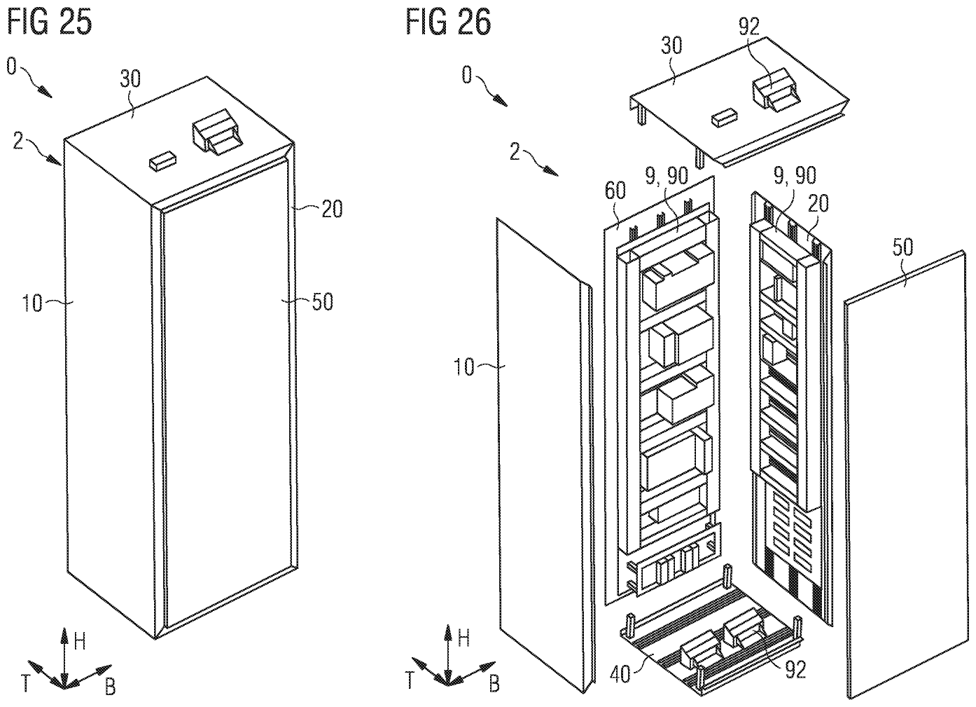

In the drawing, which is given merely by way of example, FIGS. 1 to 12 show a basic construction of a first embodiment of an electronics cabinet according to the invention for a vehicle, in particular a rail vehicle. FIGS. 13 to 17 show mechanical follow-up machining of cabinet walls for assembly of the first embodiment of the electronics cabinet. FIGS. 18 and 19 show a preassembly operation involving e-components on cabinet walls of the electronics cabinet. FIGS. 20 to 23 and 25 show assembly of the cabinet walls of the first embodiment of the electronics cabinet to form the electronics cabinet. FIGS. 24 and 25 show a second embodiment of the electronics cabinet in the form of an electronics cabinet for 19-inch components. FIG. 26 shows a third embodiment of the electronics cabinet.

The invention will be explained in more detail hereinbelow with reference to three exemplary embodiments of a variant of an electronics cabinet 0 according to the invention for a vehicle (electronics cabinet 0 for a vehicle), in particular a rail vehicle (electronics cabinet 0 for a rail vehicle). However, rather than being restricted to such a variant, such embodiments and/or the exemplary embodiments which will be explained hereinbelow, the invention is of a more basic nature, and therefore the invention can be applied to all vehicles (see above) or also to stationary electronics cabinets. The drawing illustrates only those parts of a subject matter of the invention which are necessary to provide for understanding of the invention.

The explanation of the invention on the basis of the drawing also refers hereinbelow to a width direction B or a width axis B (width B), to a height direction H or a height axis H (height H) and to a depth direction T or a depth axis T (depth T) of the electronics cabinet 0. Although the invention will be described, and illustrated, in more detail by way of preferred exemplary embodiments, the invention is not restricted by the exemplary embodiments disclosed. Other variations can be taken therefrom and/or from the above (description of the invention) without departing from the scope of protection of the invention.

FIGS. 1 and 2 show a construction of an electronics cabinet 0 according to the invention having a cabinet body 2, a cabinet frame 2 or a cabinet housing 2. A cabinet body 2 here comprises at least one cabinet wall 10, 20, 30, 40 or at least one supporting part 10, 20, 30, 40, having at least one preferred extruded profile (see below). A cabinet frame 2 here comprises a maximum of three cabinet walls 10, 20, 30, 40 or a maximum of three supporting parts 10, 20, 30, 40, each having at least one preferred extruded profile. A cabinet housing 2 here comprises a maximum of four, precisely four or at least four cabinet walls 10, 20, 30, 40 or a maximum of four, precisely four or at least four supporting parts 10, 20, 30, 40, each having at least one preferred extruded profile (cf. also FIGS. 13 and 18).

FIGS. 1 and 2 also show a door wall 50, or a cover wall 50, and a rear wall 60, each in the form of a supporting part 50, 60, each having at least one preferred extruded profile. The relevant extruded profile preferably consists of a light metal, e.g. aluminum, and combines a number of functions (cladding, supporting system(s), reinforcement, etc.) and replaces a plurality of structural parts of a conventional electronics cabinet. Instead of one or more extruded profiles, it is also possible for all the embodiments of the invention to make use of non-extruded profiles, walls, wall parts, etc.

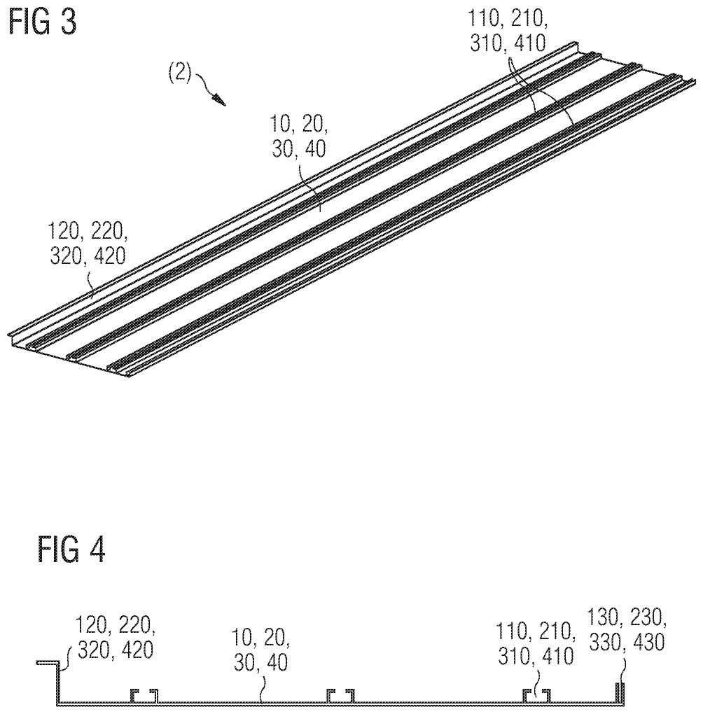

FIGS. 3 and 4 (for electronics cabinets 0 having a depth T up to approximately 600 mm) show an exemplary embodiment of an original extruded profile for example for the cabinet walls 10, 20, 30, 40, that is to say for the cabinet body 2, the cabinet frame 2 or the cabinet housing 2. A profile geometry (cross section, FIG. 4) is determined by strength-related requirements, fastening options for the e-components 9, thermal requirements, fire-protection requirements, etc. The extruded profile has longitudinal grooves 110, 210, 310, 410 for the fastening of an e-component 9 and/or of some other component and also for example for the fastening of an installation panel with the aid of a connecting part and/or of a fastening part, e.g. a T-bolt and/or a slot nut.

A preferred preferably L-shaped profile limb 120, 220, 320, 420 on the extruded profile is provided for fastening and/or sealing of the door wall 50. During assembly (final assembly) of the electronics cabinet 0, the rear wall 60 is pushed into a preferred profile mount 130, 230, 330, 430 and preferably clamped therein. The profile mount 130, 230, 330, 430 preferably has an in particular narrow U-shaped cross section (cf. bottom center of FIG. 21). A length of the extruded profile is dependent on a height H and/or a width B of the electronics cabinet 0. It is also the case here that the width B corresponds to a depth T of the electronics cabinet 0 (essentially square top wall 30 and base wall 40). Other dimensions can, of course, be used.

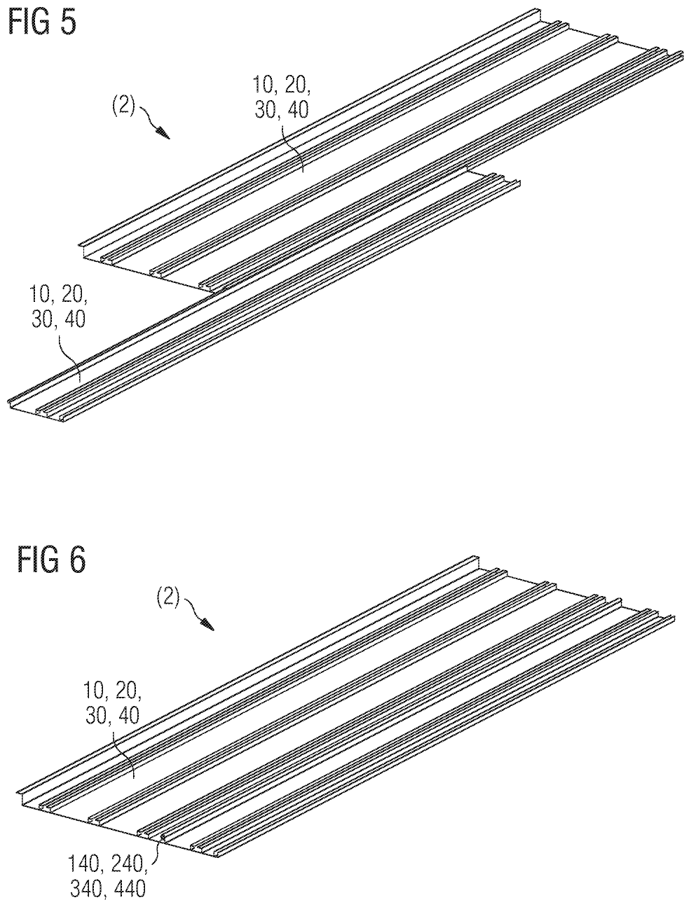

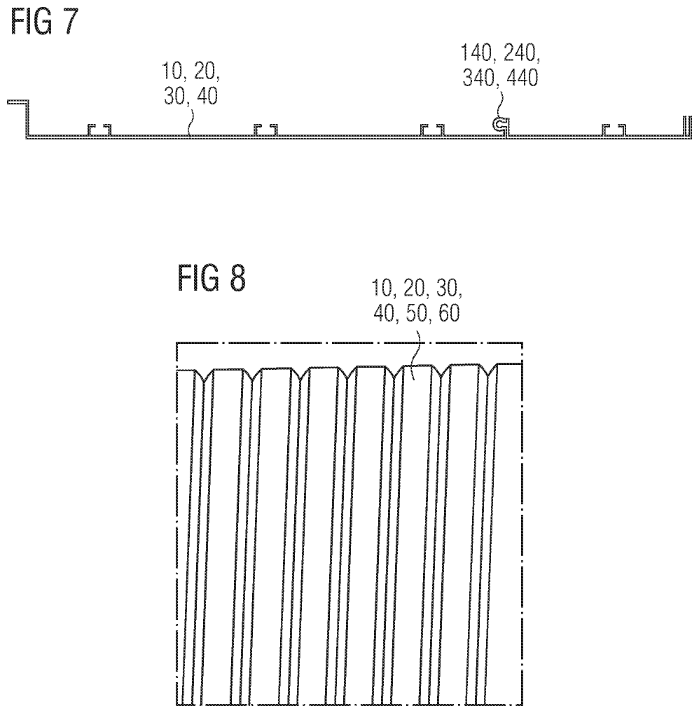

Comparatively deep T electronics cabinets 0 (cf. FIGS. 5 to 7 for electronics cabinets 0 having a depth of more than approximately 600 mm) have, possibly for specific side walls 10, 20, 30, 40, 50, 60, a plurality of combined supporting parts 10, 20, 30, 40, (50), (60) and/or possibly single-piece supporting parts (10), (20), (30), (40), 50, 60. Compatible supporting parts here (combined supporting part 10, 20, 30, 40, (50), (60)) are preferably provided or fastened on one another, preferably in a releasable manner, by means of a groove/tongue connection 140, 240, 340, 440 (FIG. 7).

Depending on design-related requirements, the extruded profiles 10, 20, 30, 40, 50, 60 can have smooth or structured surfaces (cf. FIG. 8). Such a structure is for example corrugated, and has ribs and/or grooves, etc. In the case of an internally and/or externally structured surface, considerably more heat can be dissipated over a surface of the electronics cabinet 0. Of course, all this, that is to say what has been said in relation to FIGS. 3 to 7, can also be applied to at least one cabinet wall 50, 60.

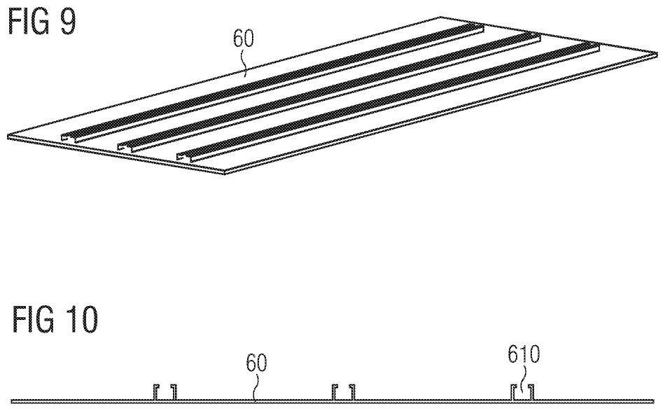

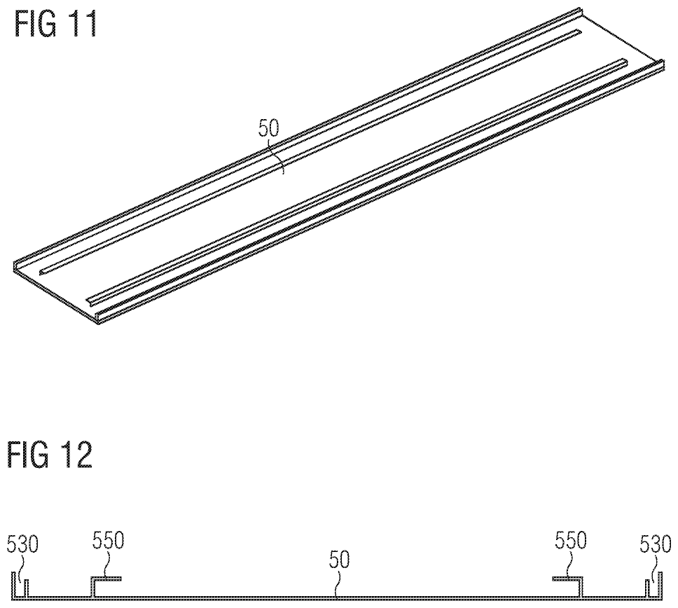

FIGS. 9 and 10 show an exemplary embodiment of the rear wall 60 with preferably at least one longitudinal groove 610 for the fastening of an e-component 9 and/or of some other component. FIGS. 11 and 12 show an exemplary embodiment of the door wall 50 (preferably no longitudinal groove). At least one profile mount 530 on the door wall 50 is provided for the attachment of a door seal and/or of a fitting. It is possible here for the profile mount 530 to be designed in the form of a U with preferably a relatively short limb (preferably on the inside). Preferably at least one profile limb 550 is provided for the fastening of small parts and can also serve to provide stability for the door wall 50. Of course, all this, that is to say what has been said in relation to FIGS. 8 to 12, can also be applied to at least one cabinet wall 10, 20, 30, 40.

Depending on a desired design of the electronics cabinet 0, the extruded profiles have to be subjected to mechanical follow-up machining (FIGS. 13 to 17) prior to being assembled together to form the electronics cabinet 0. Thus, in a first step (FIGS. 13 to 15), all the necessary cutouts 710 and/or bores 710, etc., for cabinet fastening, a cable-entry point (plug) and/or a fitting, etc., can be made in a preferably single extruded profile for the cabinet body 2, the cabinet frame 2 or the cabinet housing 2 (cf., in particular, FIG. 14). Of course, this applies equally to the extruded profiles of the cabinet walls 50, 60.

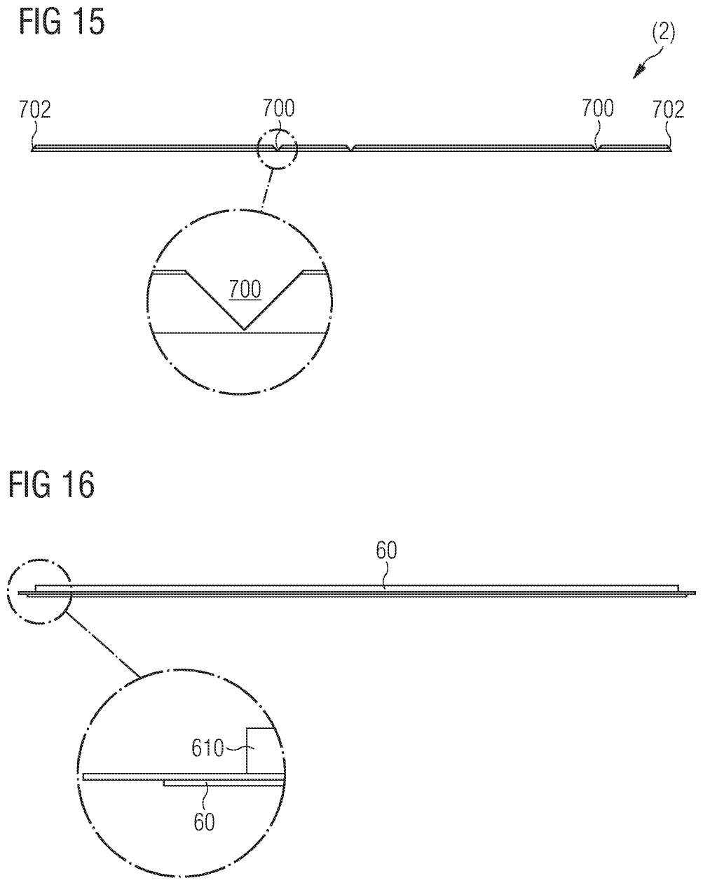

In a second step, preferably V-shaped cutouts 700 and/or beveled cutouts 702 can be made, in particular milled, in a manner corresponding to a height H and a width B of the electronics cabinet 0, in the preferably single extruded profile for the cabinet body 2, the cabinet frame 2 or the cabinet housing 2 (cf. FIG. 15). One dimension of the supporting parts 10, 20 corresponds to the height H of the side walls 10, 20; and one dimension of the supporting parts 30, 40 corresponds to the width B of the electronics cabinet 0 (top wall 30 and base wall 40).

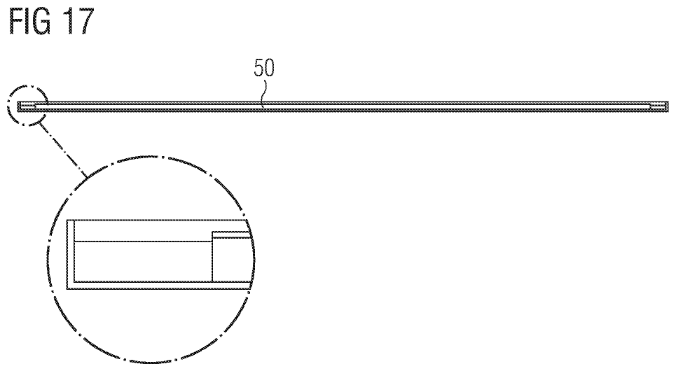

Depending on a desired design of the electronics cabinet 0, it is possible, during mechanical follow-up machining of the rear wall 60 or of an extruded profile of the rear wall 60, to mill a region around the longitudinal grooves 610 and/or a region around a cooling device (FIG. 16). Depending on a desired design of the electronics cabinet 0, it is also possible, during mechanical follow-up machining of the door wall 50 or of an extruded profile of the door wall 50, to mill a region around a profile mount 530, a profile limb 550 and/or a bent portion of a lug (FIG. 17).

Depending on a design of the electronics cabinet 0, on machining-related outlay, on the planned number of electronics cabinets 0 to be produced, and therefore on costs, it is also possible for at least one housing component (e.g. the door wall 50) to be designed in the form of a bent sheet-metal part or in some other manner.

An assembly operation of the electronics cabinet 0, or an assembly sequence for the electronics cabinet 0, e.g. using e-components 9 (92) of a control system for rail vehicles, will be explained in more detail hereinbelow (FIGS. 18 to 23 and 25), wherein in the first instance e-components 9 are preassembled on a single extruded profile or on some other arrangement for the cabinet body 2, the cabinet frame 2 or the cabinet housing 2, or on the cabinet body 2, the cabinet frame 2 or the cabinet housing 2 and/or the rear wall 60 (FIGS. 18 and 19).

The preassembly operation can involve for example positioning and/or fastening of a preassembled and/or pre-wired e-panel 90 (e-component 9) with components of a vehicle instrumentation and control system. The relevant e-panel 90 can be displaced in a stepless manner, and positioned, in the longitudinal direction B, H of the extruded profile or of the other arrangement. Fastening, in particular on at least one subsequent cabinet wall 10, 20 or a supporting part 10, 20, takes place on/in the longitudinal grooves 110, 210 by means of T-bolts or using slot nuts and bolts (cf. detail from FIG. 18, on the left).

It is also possible for cable bushings 92 and other components (plugs) to be positioned and fastened for example on at least one subsequent cabinet wall 30, 40 or a supporting part 30, 40. In addition, a preassembled and/or pre-wired e-panel 90 (e-component 9) with components of a vehicle instrumentation and control system, plugs and other components can be positioned and/or fastened in an analogous manner on the rear wall 60. This can also apply to the door wall 50, although it is not the case here.

It is only at a point in time thereafter that the electronics cabinet 0 is combined with components of the control system (FIG. 20). At a point in time after the preassembly operation of the e-components 9 (FIGS. 18 and 19), in the first instance preferably two supporting parts 40/30, 20/10 (one for a side wall 20/10 and one for the top wall or base wall 40/30) are bent toward one another and fixed mechanically in the region of the V-shaped cutouts 700. Depending on a design of the electronics cabinet 0, on fire-protection requirements, on mechanical loading which is to be expected, on manufacturing options, etc., the mechanical connection of the supporting parts 40/30, 20/10 takes place either by adhesive bonding (bottom left of FIG. 20), by welding (bottom center left of FIG. 20), by connecting elements being inserted (bottom center right of FIG. 20) or with the aid of connecting elements being screwed in (bottom right of FIG. 20).

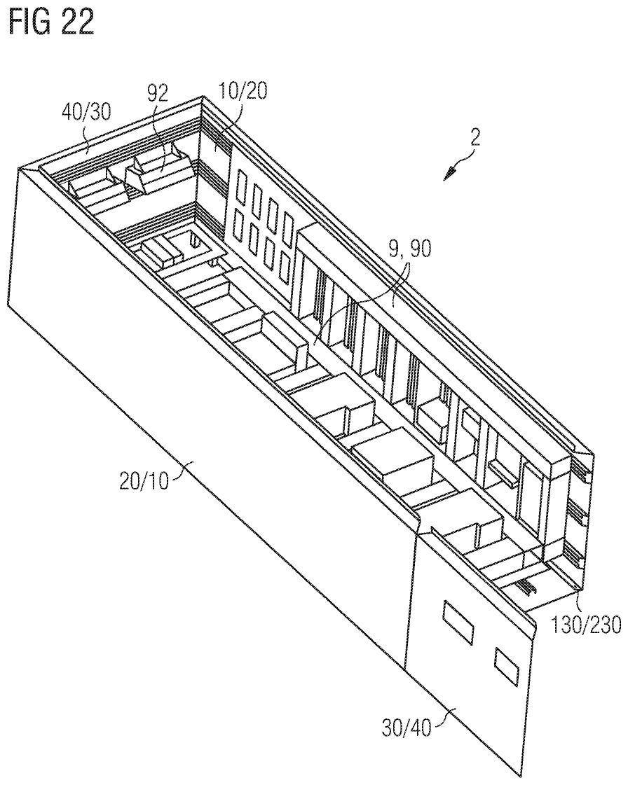

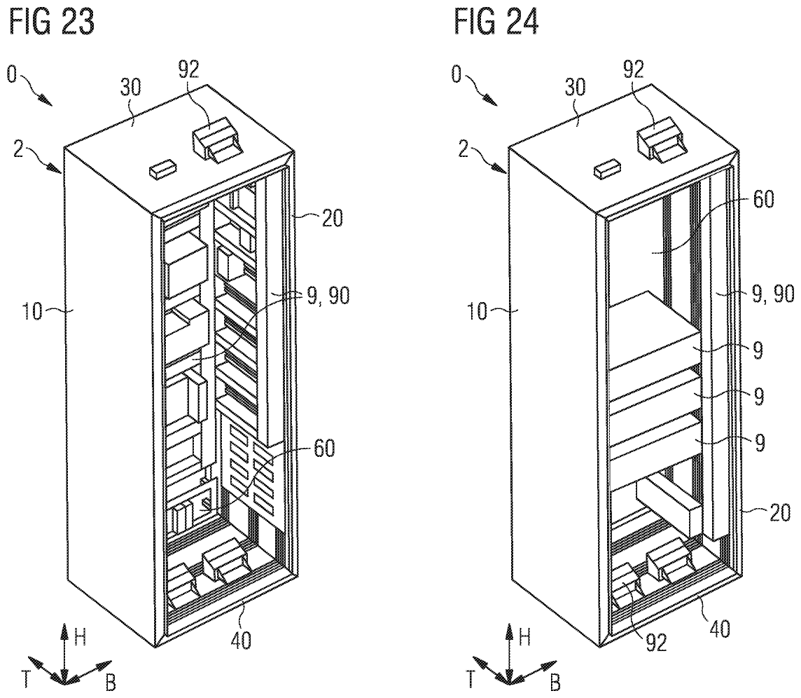

Once preferably just two supporting parts 40/30, 20/10 (side wall 20/10 and top wall or base wall 40/30) have been bent toward one another (preferably 90° angle), the preassembled rear wall 60 is pushed into the supporting part 20/10 (profile mount 130/230) and placed in position (FIG. 21). Sealing is carried out if required. The same can apply to the supporting part 40/30. At a point in time thereafter (FIG. 22), the supporting part 20/10 and then the supporting part 30/40 are bent analogously. During the bending operation, the rear wall 60 (supporting part 60) is clamped by means of the profile mounts 230/130, 330/430 of the supporting parts 20/10, 30/40. A joining operation in the region of the V-shaped cutouts 700 takes place as described above (FIG. 20). Sealing can be carried out, once again, if required. Thereafter, additional electrical connections, etc., can be provided/introduced. FIG. 23 shows the virtually finished electronics cabinet 0 (without a door wall 50 or cover wall 50) in an upright position. FIG. 25 shows the finished electronics cabinet 0.

FIG. 24 shows, in a manner analogous to FIG. 23, a virtually finished electronics cabinet 0 (second embodiment) for 19-inch e-components 9. A preassembly operation of such an electronics cabinet 0 takes place in a manner similar to that illustrated in FIG. 18. Here, instead of e-components 9, it is installation rails 90 for the fastening of 19-inch e-components 9, cable bushings 92 and other components, etc., which are placed in position and fixed. That is to say assembly takes place in a manner analogous to FIGS. 18 to 23, but, instead of e-components 9, it is preferably installation rails 90 for the fastening of the 19-inch e-components 9 which are installed.

It is also possible for holders for 19-inch e-components 9 to be installed, and for the 19-inch e-components 9 to be fastened, in the assembled cabinet body 2, the assembled cabinet frame 2 or the assembled cabinet housing 2, preferably including the rear wall 60. Thereafter, necessary electrical connections are set up and the door wall 50, or the cover wall 50, is installed. In an analogous manner, FIG. 25 shows the finished 19-inch electronics cabinet 0 with a door wall 50, or cover wall 50.

An alternative construction of the electronics cabinet 0 (third embodiment) is shown in FIG. 26. A cabinet housing 2 preferably comprises the side walls 10, 20, a top wall 30, a base wall 40, a rear wall 60 and a door wall 50 or cover wall 50. It is possible for all the walls 10, 20, 30, 40, 50, 60, or also just some of them, to be constructed, as is also the case above (first and second embodiments), from an extruded profile for example made of a light metal, e.g. aluminum. The extruded profile combines a number of functions and replaces a plurality of conventional housing parts. The machining of the extruded profiles takes place, by way of the V-shaped cutouts 700, the beveled cutouts 702, etc., in a manner similar to that described above.

An assembly sequence (once again preassembly and final assembly) for the electronics cabinet 0 using components of the control system will be explained briefly hereinbelow. Within the context of the preassembly operation, the preassembled and pre-wired e-panels 90 (e-component 9) with components of the vehicle instrumentation and control system are placed in position and fastened (see above). The e-panels 90 can be displaced in a stepless manner, and placed in position, in each case in the longitudinal direction B, H of the extruded profiles or of any other arrangements (cf. above). Cable bushings 92 (see above) and other components are also placed in position and fastened.

During the final assembly operation of the electronics cabinet 0 with components of the control system, all the walls 10, 20, 30, 40, 50, 60 are connected with the aid for example of connecting elements which are screwed in (see above, cf. bottom right of FIG. 20). The preassembled rear wall 60 is pushed into corresponding supporting parts (cf. also above) and placed in position. Sealing is carried out if required. It is also possible to provide or introduce additional electrical connections. In addition, fastening of the door wall 50, or of the cover wall 50, preferably takes place.

The invention describes a design and an assembly operation of electronics cabinets 0 for installation of e-components 9 (possibly also other components). The electronics cabinets 0 are simplified according to the invention by virtue of a development and use of at least one multifunctional extruded profile preferably made of a light metal. The cabinet body 2 according to the invention, the cabinet frame 2 according to the invention or the cabinet housing 2 according to the invention comprises, partially or fully, a multifunctional extruded profile. The multifunctional extruded profile combines a number of functions, e.g.: a cladding, at least one supporting system for integration of the e-components 9, reinforcement, cooling surfaces, etc., and replaces a number of housing parts from the prior art. The rear wall 60 and/or the door wall 50, or the cover wall 50, can likewise be formed from possibly in each case one extruded profile and likewise combine a number of functions.

Following mechanical machining of the extruded profiles, a plurality of mechanical, electrical and/or electronic, etc., e-components 9 are positioned, fastened, and if required wired, on the extruded profiles. Fastening of the e-components 9 takes place by means of the longitudinal grooves 110, 210, 310, 410, 610, in the extruded profiles for example via T-bolts or slot nuts. This provides for subsequent displacement of the e-components 9. The e-components 9 can be installed without any additional holders being attached. The electronics cabinet 0 is assembled by virtue of cabinet walls 10, 20, 30, 40 being bent and connected to form the cabinet body 2, the cabinet frame 2 or the cabinet housing 2. Using extruded profiles with a structured, e.g. corrugated or ribbed, surface allows considerably more heat to be dissipated from an electronics cabinet 0.

1-12. (canceled)

13. An electronics cabinet for an installation of electronic components, the electronics cabinet comprising:
a plurality of cabinet walls formed as supporting parts, wherein at least one of said supporting parts is substantially formed of at least one, or precisely one, extruded profile.

14. The electronics cabinet according to claim 13 configured for a installation of electronic components of a vehicle.

15. The electronics cabinet according to claim 13, wherein:
one of said cabinet walls is a door wall and/or one of said cabinet walls is a rear wall of the electronics cabinet, wherein said door wall and/or said rear wall is substantially made up of at least one, or precisely one, extruded profile; and/or
one, two, three, four, or more cabinet walls are configured in a form of a cabinet body, a cabinet frame, or a cabinet housing, and wherein said cabinet body, said cabinet frame, or said cabinet housing is substantially made up of at least one, or precisely one, extruded profile.

16. The electronics cabinet according to claim 15, wherein:
said cabinet body has at least one supporting part, and said cabinet body is made up of precisely one extruded profile, precisely two extruded profiles, or at least one extruded profile;
said cabinet frame has a maximum of three or precisely three supporting parts, and said cabinet frame is made up of precisely one extruded profile, precisely two extruded profiles, or at least one extruded profile;
said cabinet housing has a maximum of four, precisely four or at least four supporting parts, and said cabinet housing is made up of precisely one extruded profile, precisely two extruded profiles or at least one extruded profile;
one of said cabinet walls comprises precisely one supporting part, and said supporting part is made up of precisely one extruded profile, precisely two extruded profiles, or at least one extruded profile; and/or
a rear wall of said plurality of walls comprises precisely one supporting part, and said supporting part is made up of precisely one extruded profile, precisely two extruded profiles, or at least one extruded profile.

17. The electronics cabinet according to claim 13, wherein:
a cabinet body has at least one supporting part, and said cabinet body is made up of precisely one extruded profile, precisely two extruded profiles, or at least one extruded profile;
a cabinet frame has a maximum of three or precisely three supporting parts, and said cabinet frame is made up of precisely one extruded profile, precisely two extruded profiles, or at least one extruded profile;
a cabinet housing has a maximum of four, precisely four or at least four supporting parts, and said cabinet housing is made up of precisely one extruded profile, precisely two extruded profiles or at least one extruded profile;
one of said cabinet wall comprises precisely one supporting part, and aid supporting part is made up of precisely one extruded profile, precisely two extruded profiles, or at least one extruded profile; and/or
a rear wall comprises precisely one supporting part, and said supporting part is made up of precisely one extruded profile, precisely two extruded profiles, or at least one extruded profile.

18. The electronics cabinet according to claim 17, wherein:
at a point in time prior to an assembly operation of the electronics cabinet, said cabinet body, said cabinet frame, or said cabinet housing is or are formed in one piece or integrally;
said supporting part is formed in one piece or integrally;
at a point in time prior to an assembly operation of the electronics cabinet, supporting parts are connected in one piece to one another or formed integrally;
said cabinet wall is formed in one piece or integrally;
at a point in time prior to an assembly operation of the electronics cabinet, cabinet walls are connected in one piece to one another or formed integrally.

19. The electronics cabinet according to claim 17, wherein at least one of the following is true:
all of said cabinet walls or supporting parts of the electronics cabinet are produced from precisely two, precisely three, precisely four, precisely five, or precisely six different original extruded profiles;
all of said cabinet walls or supporting parts of the cabinet body, of said cabinet frame, or of said cabinet housing are produced from precisely one original extruded profile, or from precisely two different, original extruded profiles; and/or
said door wall and/or said cabinet wall are each produced from a single original extruded profile or from different original extruded profiles.

20. The electronics cabinet according to claim 13, wherein:
said extruded profile is produced from a light metal;
said extruded profile is a solid profile;
said cabinet wall has internal and/or external structuring;
said cabinet wall is formed, on an inside thereof, with at least one longitudinal groove for fastening an e-component; and/or
the electronics cabinet houses at least one e-component.

21. The electronics cabinet according to claim 20, wherein said light metal is aluminum.

22. The electronics cabinet according to claim 20, wherein the electronics cabinet is produced by an assembly method according to claim 23.

23. A method for assembling an electronics cabinet for installation of one or more e-components, the method comprising:
providing at least two cabinet walls for the electronics cabinet;
in a first instance, within a preassembly operation, installing at least one e-component on an extruded profile for a cabinet body, a cabinet frame, or a cabinet housing, and/or a rear wall of the electronics cabinet; and
subsequently, within a final assembly operation, mounting the at least two cabinet walls to one another in a final position in the electronics cabinet.

24. The assembly method according to claim 23, which comprises assembling an electronics cabinet of a vehicle and installing one or more e-components of the vehicle in the electronics cabinet.

25. The assembly method according to claim 23, which comprises assembling an electronics cabinet of a rail vehicle and installing one or more e-components of the rail vehicle.

26. The assembly method according to claim 23, which comprises, in preparation for an assembly of the electronics cabinet:
forming a cutout and/or a bore in an extruded profile for the cabinet body, for the cabinet frame, or the cabinet housing, and/or the cabinet wall;
forming a cutout and/or a beveled cutout, corresponding to a height and a width of the electronics cabinet, in the extruded profile for the cabinet body, the cabinet frame or the cabinet housing;
machining the rear wall in a region around a longitudinal groove and/or in a region of a cooling device; and/or
machining the door wall in a region around a profile mount, a profile limb, and/or a bent portion of a lug.

27. The assembly method according to claim 23, which comprises, within a preassembly operation:
installing the e-component in or on a longitudinal groove of the extruded profile for the cabinet body, the cabinet frame, or the cabinet housing, and/or the rear wall;
providing the e-component for substantially continuous displacement along the longitudinal groove; and
installing a cable bushing and/or another component on the extruded profile for the cabinet body, the cabinet frame, or the cabinet housing, and/or the rear wall.

28. The assembly method according to claim 23, which comprises, within a final assembly operation:
in a first instance, bending the extruded profile for the cabinet body, the cabinet frame, or the cabinet housing at an angle;
subsequently installing the rear wall at the angle of the extruded profile for the cabinet body, the cabinet frame, or the cabinet housing;
subsequently bending the extruded profile for the cabinet body, the cabinet frame, or the cabinet housing to form a U-shaped extruded profile on the rear wall;
subsequently bending the extruded profile for the cabinet body, the cabinet frame, or the cabinet housing to form a circumferentially completely closed extruded profile on the rear wall; and
subsequently installing a door wall on the cabinet body, the cabinet frame, or the cabinet housing.

29. The assembly method according to claim 23, which comprises forming the electronics cabinet according to claim 13.

30. A vehicle, comprising: an electronics cabinet according to claim 13 and/or an electronics cabinet produced by an assembly method according to claim 23.

31. The vehicle according to claim 30 being a rail vehicle.
